(19) United States
(12) Patent Application Publication
(10) Pub. No.: US 2025/0291966 A1
(43) Pub. Date: Sep. 18, 2025

(54) PREDICTING MECHANICAL DAMAGE IN UNDERBALANCED DRILLING

(71) Applicant: ARAMCO SERVICES COMPANY, Houston, TX (US)

(72) Inventor: Yanhui Han, Houston, TX (US)

(73) Assignee: ARAMCO SERVICES COMPANY, Houston, TX (US)

(21) Appl. No.: 18/608,087

(22) Filed: Mar. 18, 2024

(51) Int. Cl. G06F 30/17

(52) U.S. Cl. CPC G06F 30/17

(57) ABSTRACT

In general, in one aspect, embodiments disclosed herein relate to a method for optimizing underbalanced drilling according to depth of damage. The method includes collecting in situ conditions, well conditions, and formation properties of a subterranean area of interest, calculating changes of in situ stresses induced by a pressure drop inside the wellbore, creating an underbalanced drilling model using the in situ conditions, well conditions, and formation properties, modeling the drilling process, extracting and evaluating plastic mechanical damage from the underbalanced drilling model, adjusting a pre-drilling plan based on the depth of plastic mechanical damage, and finally using the modeled drilling process to drill a well. The in situ stresses include a maximum and minimum confining stress. The underbalanced drilling model includes a mechanical simulation of a first area representing rock surrounding the wellbore, and a second area representing rock inside the wellbore.

### BACKGROUND

In the process of drilling a well, the stability of the rock surrounding the wellbore is of significant concern. Accurately characterizing the stability of a wellbore under various drilling conditions enables a drill operator to optimize the drilling process.

Underbalanced drilling has recently seen a resurgence because of its advantage in minimizing formation damage (i.e., the invasion of drilling fluid into the reservoir rock), increasing rate of penetration (ROP), reducing lost circulation, eliminating differential sticking, and reducing water loss. However, with underbalanced drilling, a major disadvantage when compared to overbalanced drilling, is that underbalanced drilling is much more likely to induce plastic mechanical damage to the surrounding rock mass, which may cause wellbore instability. Therefore, it is of critical importance to evaluate the plastic mechanical damage and its depth for a designed unbalanced drilling plan at the pre-drill stage.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments disclosed herein relate to a method for optimizing underbalanced drilling according to depth of damage. The method includes collecting in situ conditions, well conditions, and formation properties of a subterranean area of interest, calculating changes of in situ stresses induced by a pressure drop inside the wellbore, creating an underbalanced drilling model using the in situ conditions, well conditions, and formation properties, modeling the drilling process, extracting and evaluating plastic mechanical damage from the underbalanced drilling model, adjusting a pre-drilling plan based on the depth of plastic mechanical damage, and finally using the modeled drilling process to drill a well. The in situ stresses include a maximum and minimum confining stress. The underbalanced drilling model includes a mechanical simulation of a first area representing rock surrounding the wellbore, and a second area representing rock inside the wellbore. The underbalanced drilling model includes stress changes in the first area and the second area. Modeling of the drilling process is accomplished by repeatedly reducing the stress borne by the second area in increments and solving the underbalanced drilling model to mechanical equilibrium to determine the stress borne in the first area.

In general, in one aspect, embodiments disclosed herein relate to a non-transitory computer readable medium storing instructions on a memory coupled to a processor. The instructions include collecting in situ conditions, well conditions, and formation properties of a subterranean area of interest, calculating changes of in situ stresses induced by a pressure drop inside the wellbore, creating an underbalanced drilling model using the in situ conditions, well conditions, and formation properties, modeling the drilling process, extracting and evaluating plastic mechanical damage from the underbalanced drilling model, and adjusting a pre-drilling plan based on the depth of plastic mechanical damage. The in situ stresses include a maximum and minimum confining stress. The underbalanced drilling model includes a mechanical simulation of a first area representing rock surrounding the wellbore, and a second area representing rock inside the wellbore. The underbalanced drilling model includes stress changes in the first area and the second area. Modeling of the drilling process is accomplished by repeatedly reducing the stress borne by the second area in increments and solving the underbalanced drilling model to mechanical equilibrium to determine the stress borne in the first area.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1 is a force diagram in accordance with one or more embodiments.

FIG. 2 is a computational mesh in accordance with one or more embodiments.

FIG. 3A and FIG. 3B are plastic shear strain diagrams in accordance with one or more embodiments.

FIG. 4A and FIG. 4B are effective normal stress diagrams in accordance with one or more embodiments.

FIG. 5 shows a drilling cross section in accordance with one or more embodiments.

FIG. 6 is a flowchart in accordance with one or more embodiments.

FIG. 7 shows a computer system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (for example, first, second, third) may be used as an adjective for an element (that is, any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

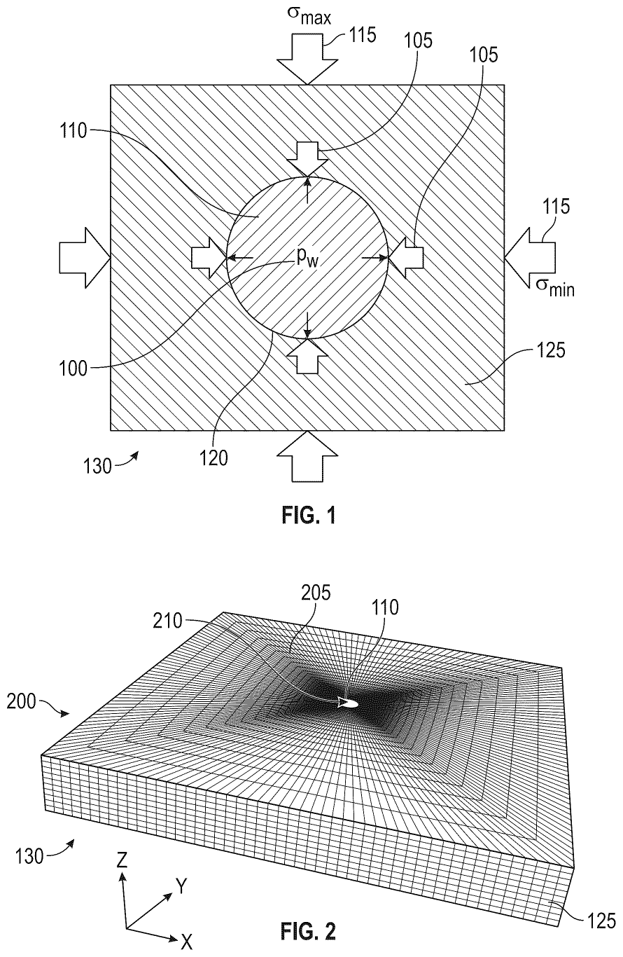

In the following description of FIGS. 1-7, any component described regarding a figure, in various embodiments disclosed herein, may be equivalent to one or more like-named components described with regard to any other figure. For brevity, descriptions of these components will not be repeated regarding each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment which may be implemented in addition to, in conjunction with, or in place of the embodiments described with regard to a corresponding like-named component in any other figure.

It is to be understood that the singular forms “a,” “an,” and “the” include plural referents unless the context clearly dictates otherwise. Thus, for example, reference to “an operator” includes reference to one or more of such operators.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that one or more of the steps shown in the flowcharts may be omitted, repeated, and/or performed in a different order than the order shown. Accordingly, the scope disclosed herein should not be considered limited to the specific arrangement of steps shown in the flowcharts.

Embodiments disclosed herein relate to a process for predicting the depth of plastic mechanical damage in a planned wellbore in order to estimate the stability of a well drilled in the predicted fashion. More specifically, a novel method is discussed herein to predict the plastic mechanical damage and its depth in underbalanced drilling. This method can realistically capture the progressive cutting and removal of the rocks in the borehole space and the corresponding effects on the stress redistribution and development of plastic mechanical damage around the wellbore. It also catches the depletion effect induced by the fluid pressure drop inside the borehole on the stress state around the wellbore. This information can then be used to refine a drilling plan and optimize drilling performance while ensuring the stability of the resulting well. Using depth of damage to estimate well stability can provide more accurate and consistent estimates over width and volume of damage stability estimates.

FIG. 1 is a force diagram representing the in-situ downhole condition during underbalanced drilling in accordance with one or more embodiments. In underbalanced drilling, the wellbore pressure 100 (p_{w}) is less than the pore pressure 105 (p₀). This can complicate the process of drilling a wellbore 110 under such conditions. This complication arises chiefly from the fact that with the pore pressure 105 being greater than the wellbore pressure 100, the principal in situ stresses 115 can lead to plastic mechanical damage outward from the wall 120 of the wellbore 110 through the rock 125 in the subterranean area of interest 130. Rock 125 within a subterranean area of interest 130 may be of one or more types. The principal in situ stresses 115 also known as principal confining stresses, are represented by σₘₐₓ and σₘᵢₙ as the maximum and minimum principal confining stresses.

There are two key physical processes that may be observed from FIG. 1. First, the fluid pressure in the borehole is reduced from the original pore pressure 105 to the target wellbore pressure 100 in underbalanced drilling. This fluid pressure change in the rock inside the borehole space causes a stress change in the surrounding rock mass. Second, the cutting and removal of the rock inside the borehole is a progressive process. Initially, the rock inside the borehole is intact, and thus provides strong support to the surrounding rock mass. As the drilling progresses, the rock inside the borehole is fragmented, and the effective stress in the rock inside the borehole is progressively reduced, until it eventually becomes zero. The rock fragments are then circulated to the ground surface by the circulating fluid.

In one or more embodiments, the force diagram of FIG. 1 is used to realistically model this progressive process because the process primarily affects the initiation and evolution of plastic mechanical damage around the wellbore 110. For example, if the rock inside the borehole space is simulated as being removed suddenly or very quickly, dynamic effects may be unduly incorporated into the simulation and thus the plastic mechanical damage volume may be overestimated.

FIG. 2 is a computational mesh in accordance with one or more embodiments. In order to best model the stresses and mechanical changes in the subterranean area of interest 130 during the drilling process, mechanical simulation models may be used. The mechanical simulation model may be generated using a computer. Mechanical simulation may involve generating a computational mesh 200 that includes a computer model of the area to be studied that includes the material properties as well as initial stress parameters. To model the progressive process of drilling a wellbore 110, the computational mesh 200 is divided into two areas. The first area 205 represents the section of rock 125 surrounding the wellbore 110. The second area 210 represents the section of rock 125 within the path of the wellbore 110. Modeling the progressive process of drilling may involve a series of stages. Each stage involves first reducing the stress borne by the rock 125 in the second area 210 by a small increment, then calculating the amount of stress borne in the first area 205 as well as the resulting strain. The increments by which the stress in the second area 210 may be reduced is by such a small amount that the number of stages in a simulation would number in the thousands. For example, the stress borne by the rock 125 in the second area 210 could be reduced by 0.02% of the total initial stress of the second area 210. As wellbore drilling being simulated in this context is a quasistatic process, the slower the reduction of stress in the simulation, the smoother the results are in general. Once there are about 5000 reduction steps for a given stage of drilling, the results are unlikely to change if further steps are used. To simulate the downhole far-field condition, the in situ conditions may be applied to the boundaries of the underbalanced drilling model. The computational mesh 200 may represent a segment of the planned wellbore 110. Accordingly, the process of modeling drilling a well may involve using a series of computational meshes 200 to model the full wellbore 110 in increments along the length of the wellbore 110.

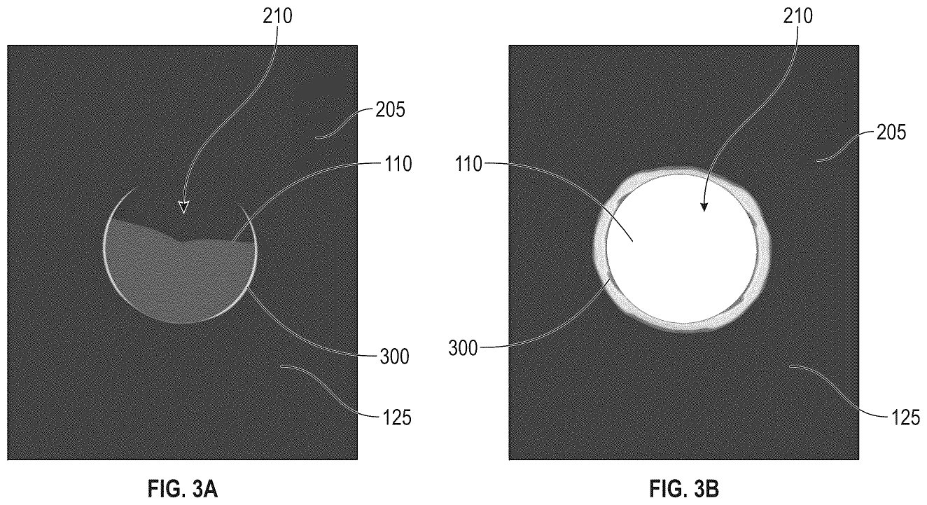

FIG. 3A and FIG. 3B are plastic shear strain diagrams in accordance with one or more embodiments. FIG. 3A shows an example of the plastic shear strain 300 in the first area 205 and the second area 210 when the stress borne by the second area 210 is reduced to half of the original stress. FIG. 3B shows an example of the plastic shear strain 300 in the first area 205 and the second area 210 when the stress borne by the second area 210 is reduced to zero. Plastic shear strain occurs in the locations where the maximum shear stress exceeds the rock's compressive load bearing ability before plastically deforming. From measuring the depth of this predicted plastic deformation radially out from the wellbore, the likelihood of a significant wellbore collapse can be determined. The likelihood of collapse increases with increasing depth of damage and the anticipated threshold is determinable from the rock properties and principal confining stresses. At each computational step in the mechanical simulation, the stresses in each element are calculated and used to evaluate if the element has run into plastic yielding. If there is plastic yielding, the strain increment can be decomposed into plastic strain and elastic strain based on plastic flow rules.

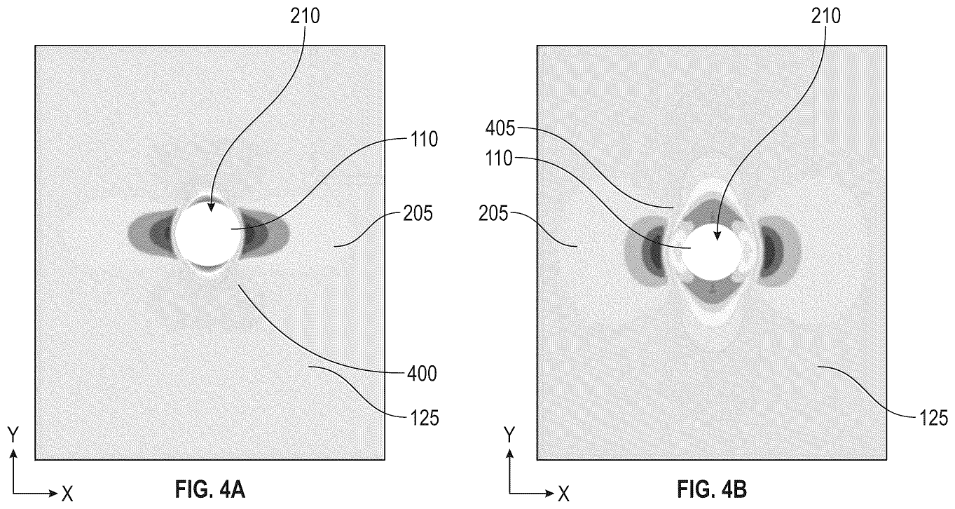

FIG. 4A and FIG. 4B are effective normal stress diagrams in accordance with one or more embodiments. FIG. 4A shows the effective normal stress in the X direction 400 when the stress borne by the second area 210 has been reduced to zero and the rock 125 in the second area 210 has been removed. FIG. 4B shows the effective normal stress in the Y direction 405 when the stress borne by the second area 210 has been reduced to zero and the rock 125 in the second area 210 has been removed. Note that the nonuniform stress distribution implies a nonuniform default stress condition. This is common for inclined and horizontal wells due to overburden pressure not being aligned with the wellbore 110. The distribution of stress in the second area 210 is used similarly to strain in that it is used to determine the depth of plastic mechanical damage in the rock surrounding the wellbore 110 which indicates the likelihood of wellbore collapse.

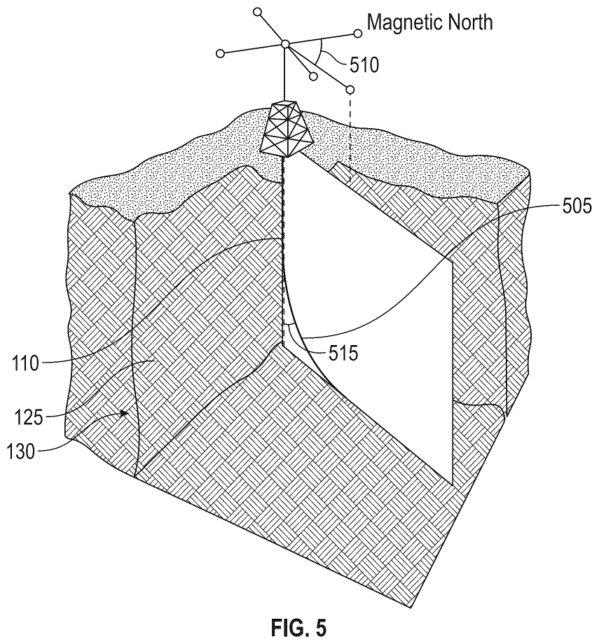

FIG. 5 shows a drilling cross section in accordance with one or more embodiments. When modelling a wellbore 110 drilling process, the features of the particular subterranean area of interest 130 as well as the characteristics of the planned well are of paramount importance. For instance, the wellbore path 505 as characterized by the azimuth 510 and inclination angle 515 determine the orientation of the wellbore 110 as well as the particular rock 125 through which the wellbore 110 is drilled. A wellbore path 505 may be modified according to a drilling simulation to account for, and optimize around, the features of the subterranean area of interest 130.

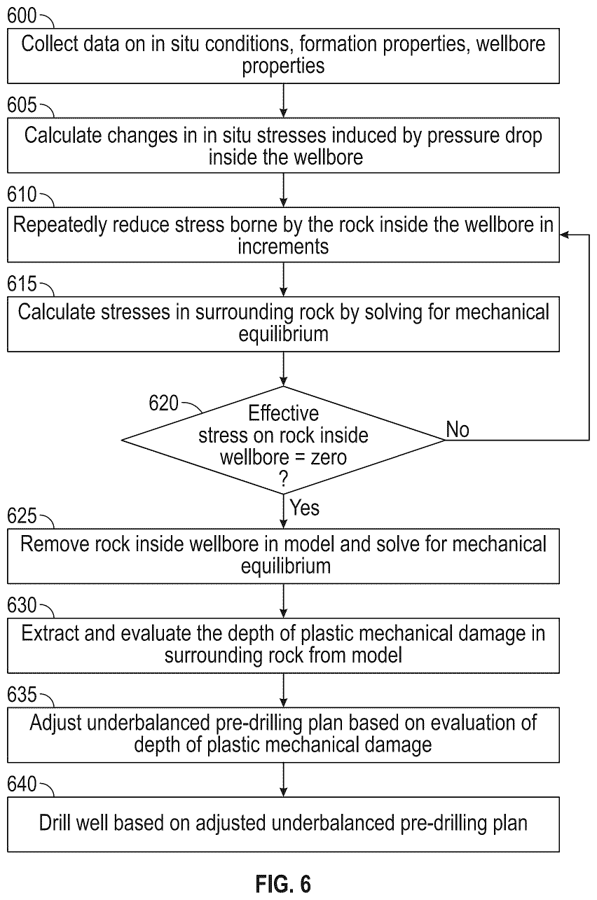

FIG. 6 is a flowchart for using an underbalanced drilling simulation to create an optimized pre-drilling plan, in accordance with one or more embodiments. In one or more embodiments, the method of FIG. 6 is performed using an underbalanced drilling simulation model. In one or more embodiments, the model is built using the computation mesh of FIG. 2.

In step 600, data on in situ conditions, formation properties, and wellbore properties is collected and fed into the mechanical simulation computer model in order to create a realistic computer simulation of the drilling process for a given section of the planned wellbore 110. In situ conditions may include, for example, vertical stress, maximum horizontal stress, minimum horizontal stress, and/or pore pressure 105. Formation properties may include, for example, bulk density, young's modulus, Poisson's ratio, cohesion, friction angle, tensile strength, and/or Biot's coefficient of effective stress. Well conditions may include, for example, wellbore radius, wellbore inclination, wellbore azimuth, and/or drilling mud pressure. Well conditions are variables that are controllable in the process of drilling the wellbore 110. In particular, wellbore azimuth and wellbore inclination determine the path of the wellbore 110. Formation properties and in situ conditions may be measured directly from the subterranean area of interest 130 or taken from geological models of similar subterranean areas of interest 130 elsewhere. Step 600 may also involve assigning the elastoplastic rock material to both regions of the computational mesh of FIG. 2 to build the underbalanced drilling simulation model.

In step 605, new in situ stresses 115 are calculated from the initial in situ stresses 115 along with the data collected in step 600 according to the following equations (1) and (2). The change in the in situ stresses 115 is induced by the drop in pressure inside the wellbore 110 that is characteristic of underbalanced drilling.

$${σ}_{Hmax}^{N} = {σ}_{Hmax} + \frac{1 - 2 v}{1 - v} α ( {p}_{w} - {p}_{0} ) \qquad ( 1 )$$

$${σ}_{hmin}^{N} = {σ}_{hmin} + \frac{1 - 2 v}{1 - v} α ( {p}_{w} - {p}_{0} ) \qquad ( 2 )$$

Where σ_{Hmax}^{N} is the new maximum confining stress, σ_{Hmax} is the initial maximum confining stress, v is Poisson's ratio, α is Biot's coefficient of effective stress, p₀ is the pore pressure 105, p_{w} is the drilling mud pressure, σₕₘᵢₙ^{N} is the new minimum confining stress, and σₕₘᵢₙ is the initial minimum confining stress. Note that in underbalanced drilling, the new minimum and maximum confining stresses are less than the initial minimum and maximum confining stresses because p_{w}<p₀. In the case of an inclined or horizontal wellbore 110, the in situ stresses 115 may need to be transformed from a global coordinate system to a local coordinate system aligned with the wellbore 110. The stress state is initialized in the model using the adjusted in-situ stresses calculated in Step 605. In one or more embodiments, the adjusted stresses are applied on the model boundaries.

In step 610, the stress borne by the rock 125 in the second area 210 is repeatedly reduced in small increments (for example, 0.02% of the initial average stress of the second area 210) This approximates the gradual drilling process of progressively weakening the rock 125 until the weakened rock flows free and is transported out of the formation and to the surface by circulating drilling fluid.

In step 615, stresses in the first area 205 are calculated for each reduction in stress borne by the rock 125 in the second area 210. Steps 610 and 615 are repeated one after another until the stress in the second area 210 is reduced to zero. The stresses in the first area 205 are calculated by solving the simulated drilling model to equilibrium. This means balancing the forces present such that Newton's third law, which states that every force has an equal and opposite force, is obeyed. A system at equilibrium is stable. At equilibrium, each element has a stress state compatible with its mechanical strength and at any node, velocities approach zero. If the stresses borne by the second area 210 are reduced, the stresses borne by the first area 205 must change to account for the new stress state. Balancing stresses in this manner to determine the location and magnitude of stresses in a model is a key component of mechanical simulation and is an inherent part of computational geomechanics software.

In step 620, the model checks the stresses borne by the rock 125 on the surface of the second area 210. If this stress is zero, the model proceeds to step 625. If this stress is greater than zero, the model returns to step 610. If the stress in the second area 210 is somehow negative, the model sets the stress in the second area 210 to zero and proceeds to step 625. In step 625, the simulated rock 125 inside the wellbore 110 is removed and the model is solved for mechanical equilibrium a final time. In step 630, the model data is extracted and the depth of plastic mechanical damage, defined by the stress and strain in the first area 205, is evaluated to determine the safety of the drilling plan. If the depth of plastic mechanical damage is less than a certain value, the planned underbalanced drilling operation can be predicted to have a low likelihood of well collapse. In step 635, the results from step 630 are used to adjust the drilling plan. This adjusted drilling plan may be evaluated again with the same process as previously described. In step 640, the final adjusted drilling plan is used to drill a well.

### Demonstrative Example

An example embodiment of the method of simulating mechanical damage, is provided below. As discussed above in Step 600, in-situ conditions, formation properties, and well conditions are collected. Example values of these three pieces of data are provided as follows:

### In-Situ Condition:

Vertical stress (σ_{V})=100 MPa
Max. hori. stress (σ_{H})=135 MPa
Min. hori. stress (σₙ)=65 MPa
Pore pressure (p₀)=55 MPa

### Rock Properties:

Bulk density (ρ)=2000 kg/m³
Young's modulus (E)=40 GPa
Poisson's ratio (v)=0.25
Cohesion (c)=15 MPa
Friction angle (φ)=40°
Tensile strength (σ^{T})=5 MPa
Biot's coefficient (α) of effective stress=0.85

### Well Conditions:

Borehole radius=0.1 m
Inclination=90°
Azimuth=85°
Drilling mud pressure (p_{w})=15 MPa

Next, new in-situ principal stresses (σₘₐₓ^{N}) (σₘᵢₙ^{N}) are calculated from the initial principal stresses (σ_{H}), (σₕ), Poisson's ratio (v), Biot's coefficient of effective stress (α), pore pressure 105 (p₀), and drilling mud pressure (p_{w}) as shown.

$${σ}_{max}^{N} = {σ}_{H}^{N} = {σ}_{H} + \frac{1 - 2 v}{1 - v} α ( {p}_{w} - {p}_{0} ) = 97.33 MPa$$

$${σ}_{min}^{N} = {σ}_{h}^{N} = {σ}_{h} + \frac{1 - 2 v}{1 - v} α ( {p}_{w} - {p}_{0} ) = 27.33 MPa$$

Once the new in-situ principal stresses are calculated, a mechanical model can be created in any suitable geomechanical modeling software known to those skilled in the art. The computational mesh is presented in FIG. 2. The model consists of two regions, i.e., the borehole region (to be drilled/excavated) in the central area (the second area 210) and rock 125 around the wellbore 110 (the first area 205). The model extends 2 meters in the x- and y-directions and 0.5 meters in the z-direction which is wellbore axis direction.

The rock 125 with properties listed above is assigned to the whole model, including the first and second areas. Then the whole model is initialized with the adjusted principal stresses. The adjusted stresses are also applied on the surfaces of all outer boundaries.

The stresses in the rock 125 in the second area 210 are progressively reduced to zero over 2500 stages. At each stage, the model is solved to mechanical equilibrium after the stress is reduced in the rock 125 inside the wellbore 110.

Finally, the plastic mechanical damage to the first area 205 is extracted from the model and evaluated. FIG. 3A shows the plastic shear strain after the stress in the rock 125 in the wellbore 110 is reduced by half. FIG. 3B shows the plastic shear strain after the rock 125 in the wellbore 110 is removed. After the wellbore 110 is drilled, the maximum plastic damage depth is 14 cm. FIG. 4A and FIG. 4B present the distributions of effective radial stress and tangential stress around the borehole after the rock 125 in the wellbore 110 is drilled.

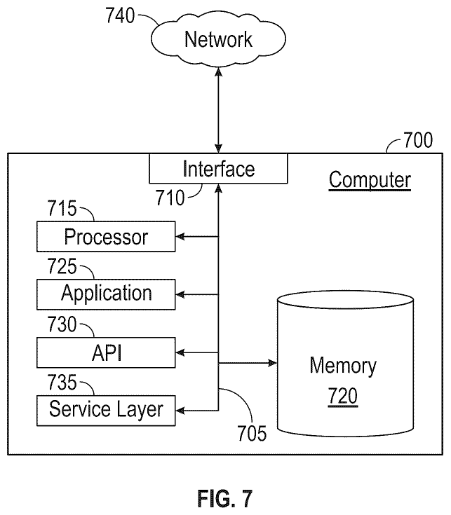

Embodiments disclosed herein may be implemented on a computer system. FIG. 7 is a block diagram of a computer system 700 used to provide computational functionalities associated with described algorithms, methods, functions, processes, flows, and procedures as described in the instant disclosure, according to an implementation. The illustrated computer 700 is intended to encompass any computing device such as a high performance computing (HPC) device, a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer 700 may include a computer that includes an input device, such as a keypad, keyboard, touch screen, or other device that can accept user information, and an output device that conveys information associated with the operation of the computer 700, including digital data, visual, or audio information (or a combination of information), or a GUI.

The computer 700 can serve in a role as a client, network component, a server, a database or other persistency, or any other component (or a combination of roles) of a computer system for performing the subject matter described in the instant disclosure. The illustrated computer 700 is communicably coupled with a network 740. In some implementations, one or more components of the computer 700 may be configured to operate within environments, including cloud-computing-based, local, global, or other environment (or a combination of environments).

At a high level, the computer 700 is an electronic computing device operable to receive, transmit, process, store, or manage data and information associated with the described subject matter. According to some implementations, the computer 700 may also include or be communicably coupled with an application server, e-mail server, web server, caching server, streaming data server, business intelligence (BI) server, or other server (or a combination of servers).

The computer 700 can receive requests over network 740 from a client application (for example, executing on another computer 700) and responding to the received requests by processing the said requests in an appropriate software application. In addition, requests may also be sent to the computer 700 from internal users (for example, from a command console or by other appropriate access method), external or third-parties, other automated applications, as well as any other appropriate entities, individuals, systems, or computers.

Each of the components of the computer 700 can communicate using a system bus 705. In some implementations, any or all of the components of the computer 700, both hardware or software (or a combination of hardware and software), may interface with each other or the interface 710 (or a combination of both) over the system bus 705 using an application programming interface (API) 1812 or a service layer 735 (or a combination of the API 730 and service layer 735. The API 730 may include specifications for routines, data structures, and object classes. The API 730 may be either computer-language independent or dependent and refer to a complete interface, a single function, or even a set of APIs. The service layer 735 provides software services to the computer 700 or other components (whether or not illustrated) that are communicably coupled to the computer 700. The functionality of the computer 700 may be accessible for all service consumers using this service layer. Software services, such as those provided by the service layer 735, provide reusable, defined business functionalities through a defined interface. For example, the interface may be software written in JAVA, C++, or other suitable language providing data in extensible markup language (XML) format or other suitable format. While illustrated as an integrated component of the computer 700, alternative implementations may illustrate the API 730 or the service layer 735 as stand-alone components in relation to other components of the computer 700 or other components (whether or not illustrated) that are communicably coupled to the computer 700. Moreover, any or all parts of the API 730 or the service layer 735 may be implemented as child or sub-modules of another software module, enterprise application, or hardware module without departing from the scope of this disclosure.

The computer 700 includes an interface 710. Although illustrated as a single interface 710 in FIG. 18, two or more interfaces 710 may be used according to particular needs, desires, or particular implementations of the computer 700. The interface 710 is used by the computer 700 for communicating with other systems in a distributed environment that are connected to the network 740. Generally, the interface (includes logic encoded in software or hardware (or a combination of software and hardware) and operable to communicate with the network 740. More specifically, the interface 710 may include software supporting one or more communication protocols associated with communications such that the network 740 or interface's hardware is operable to communicate physical signals within and outside of the illustrated computer 700.

The computer 700 includes at least one computer processor 715. Although illustrated as a single computer processor 715 in FIG. 18, two or more processors may be used according to particular needs, desires, or particular implementations of the computer 700. Generally, the computer processor 715 executes instructions and manipulates data to perform the operations of the computer 700 and any algorithms, methods, functions, processes, flows, and procedures as described in the instant disclosure.

The computer 700 also includes a memory 720 that holds data for the computer 700 or other components (or a combination of both) that can be connected to the network 740. For example, memory 720 can be a database storing data consistent with this disclosure. Although illustrated as a single memory 720 in FIG. 18, two or more memories may be used according to particular needs, desires, or particular implementations of the computer 700 and the described functionality. While memory 720 is illustrated as an integral component of the computer 700, in alternative implementations, memory 720 can be external to the computer 700.

The application 725 is an algorithmic software engine providing functionality according to particular needs, desires, or particular implementations of the computer 700, particularly with respect to functionality described in this disclosure. For example, application 725 can serve as one or more components, modules, applications, etc. Further, although illustrated as a single application 725, the application 725 may be implemented as multiple applications 725 on the computer 700. In addition, although illustrated as integral to the computer 700, in alternative implementations, the application 725 can be external to the computer 700.

There may be any number of computers 700 associated with, or external to, a computer system containing computer 700, each computer 700 communicating over network 740. Further, the term “client,” “user,” and other appropriate terminology may be used interchangeably as appropriate without departing from the scope of this disclosure. Moreover, this disclosure contemplates that many users may use one computer 700, or that one user may use multiple computers 700.

In some embodiments, the computer 700 is implemented as part of a cloud computing system. For example, a cloud computing system may include one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which may be performed using one or more Internet connections. More specifically, cloud computing system may operate according to one or more service models, such as infrastructure as a service (IaaS), platform as a service (PaaS), software as a service (SaaS), mobile “backend” as a service (MBaaS), serverless computing, artificial intelligence (AI) as a service (AIaaS), and/or function as a service (FaaS).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. A method for optimizing underbalanced drilling according to depth of damage, comprising:
collecting in situ conditions, well conditions, and formation properties of a subterranean area of interest,
wherein the subterranean area of interest is comprised of rock of one or more types;
calculating changes of in situ stresses induced by pressure drop inside a wellbore, wherein the in situ stresses comprise a maximum and minimum confining stress;
creating an underbalanced drilling model using the in situ conditions, the well conditions, and the formation properties,
wherein the underbalanced drilling model comprises a mechanical simulation of a first area representing the rock surrounding the wellbore and a second area representing the rock inside the wellbore, and
wherein the underbalanced drilling model includes stress changes in the first area and the second area;
modeling a drilling process using the underbalanced drilling model, by repeatedly:
reducing the stress borne by the second area in increments, and
solving the underbalanced drilling model to mechanical equilibrium to determine the stress borne in the first area;
removing the rock from the second area in the underbalanced drilling model to evaluate plastic mechanical damage to the surrounding rock in the first area;
extracting and evaluating plastic mechanical damage from the underbalanced drilling model;
adjusting an underbalanced pre-drilling plan based on the depth of plastic mechanical damage; and
using the modeled drilling process to drill a well using underbalanced drilling based on the evaluation of the plastic mechanical damage.

2. The method of claim 1, further comprising: applying the in situ conditions to boundaries of the underbalanced drilling model.

3. The method of claim 1, further comprising: transforming the in situ stresses from a global coordinate system to a coordinate system aligned with a path of the wellbore.

4. The method of claim 1, wherein evaluating the plastic mechanical damage comprises measuring a depth of the plastic mechanical damage in the rock surrounding the wellbore.

5. The method of claim 1, wherein the stress on the rock in the second area is calculated down to zero.

6. The method of claim 1, wherein the in situ conditions comprise at least one of:
vertical stress,
maximum horizontal stress, and
minimum horizontal stress.

7. The method of claim 6, wherein the in situ conditions are collected from measurements of the subterranean area of interest.

8. The method of claim 1, wherein the formation properties comprise at least one of:
bulk density, young's modulus, Poisson's ratio, cohesion, friction angle, tensile strength, and Biot's coefficient of effective stress.

9. The method of claim 8, wherein the formation properties are collected from measurements of the subterranean area of interest.

10. The method of claim 8, wherein the formation properties are collected from geological models of other similar subterranean areas.

11. The method of claim 1, wherein the well conditions comprise at least one of: wellbore radius, inclination, azimuth, and drilling mud pressure.

12. The method of claim 11, wherein the well conditions are variables controllable by a drilling operator.

13. The method of claim 1, further comprising: modeling the drilling process repeatedly along a plurality of segments of a planned drilling path.

14. The method of claim 1, further comprising: iteratively adjusting the well conditions over a plurality of drilling process simulations according to a drilling goal to find optimal well conditions that provide a safe wellbore damage depth.

15. The method of claim 1, further comprising: iteratively adjusting a planned drilling path over a plurality of drilling process simulations to further optimize drilling performance.

16. A non-transitory computer readable medium storing instructions on a memory coupled to a processor, the instructions comprising functionality for:
collecting in situ conditions, well conditions, and formation properties of a subterranean area of interest,
wherein the subterranean area of interest is comprised of rock of one or more types;
calculating changes of in situ stresses induced by pressure drop inside a wellbore, wherein the in situ stresses comprise a maximum and minimum confining stress;
creating an underbalanced drilling model using the in situ conditions, the well conditions, and the formation properties,
wherein the underbalanced drilling model comprises a mechanical simulation of a first area representing the rock surrounding the wellbore and a second area representing the rock inside the wellbore, and
wherein the underbalanced drilling model includes stress changes in the first area and the second area; and
modeling a drilling process using the underbalanced drilling model, by repeatedly:
reducing the stress borne by the second area in increments, and
solving the underbalanced drilling model to mechanical equilibrium to determine the stress borne in the first area;
removing the rock from the second area in the underbalanced drilling model to evaluate plastic mechanical damage to the surrounding rock in the first area;
extracting and evaluating plastic mechanical damage from the underbalanced drilling model;
adjusting an underbalanced pre-drilling plan based on the depth of plastic mechanical damage.

17. The non-transitory computer readable medium of claim 16, further comprising: instructions for modeling the drilling process repeatedly along a plurality of segments of a planned drilling path.

18. The non-transitory computer readable medium of claim 16, further comprising: instructions for iteratively adjusting the well conditions over a plurality of drilling process simulations according to a drilling goal to find optimal well conditions that provide a safe wellbore damage depth.

19. The non-transitory computer readable medium of claim 16, further comprising: instructions for iteratively adjusting a planned drilling path over a plurality of drilling process simulations to further optimize drilling performance.
